(19) United States
(12) Patent Application Publication
(10) Pub. No.: US 2025/0279589 A1
(43) Pub. Date: Sep. 4, 2025

(54) LOW-COST DUAL-POLARIZED RADIATING ELEMENTS AND RELATED BASE STATION ANTENNAS

(71) Applicant: Outdoor Wireless Networks LLC, Richardson, TX (US)

(72) Inventors: Jian Zhang, Suzhou (CN); Bin Sun, Suzhou (CN); Cheng Xue, Suzhou (CN); Changfu Chen, Suzhou (CN); Pengfei Guo, Suzhou (CN); Haifeng Li, Richardson, TX (US)

(21) Appl. No.: 19/058,144

(22) Filed: Feb. 20, 2025

(30) Foreign Application Priority Data
Mar. 1, 2024 (CN) 2024102355793

(51) Int. Cl. H01Q 21/06; H01Q 1/24

(52) U.S. Cl. CPC H01Q 21/062; H01Q 1/246

(57) ABSTRACT

Radiating elements comprise a dielectric support, first through fourth sheet metal dipole arms on the dielectric support, and a feed stalk printed circuit board. The feed stalk printed circuit board includes a first RF transmission line that has a first signal conductor that is coupled to the first sheet metal dipole arm through at least a first capacitive connection and a first ground conductor that is coupled to the second sheet metal dipole arm through at least a second capacitive connection and a second RF transmission line that has a second signal conductor that is coupled to the third sheet metal dipole arm through at least a third capacitive connection and a second ground conductor that is coupled to the fourth sheet metal dipole arm through at least a fourth capacitive connection.

### CROSS-REFERENCE TO RELATED APPLICATIONS

The present application claims priority to Chinese Patent Application No. 2024102355793, filed Mar. 1, 2024, the entire content of each of which is incorporated herein by reference.

### FIELD

The present invention generally relates to radio communications and, more particularly, to base station antennas for cellular communications systems and to radiating elements for such base station antennas.

### BACKGROUND

Cellular communications systems are well known in the art. In a cellular communications system, a geographic area is divided into a series of regions that are referred to as “cells” which are served by respective base stations. Each base station includes baseband equipment, radios and base station antennas that are configured to provide two-way radio frequency (“RF”) communications with subscribers that are positioned throughout the cell served by the base station. The base station antennas are often mounted on a tower or other raised structure, with the radiation pattern (“antenna beam”) that is generated by each antenna directed outwardly to serve a respective sector. Typically, a base station antenna includes multiple phase-controlled arrays of radiating elements, with the radiating elements arranged in vertically-extending columns that are referred to as “linear arrays.” Herein, “vertical” refers to a direction that is generally perpendicular relative to the plane defined by the horizon. References will also be made herein to the “azimuth” plane, which refers to a horizontal plane that bisects the base station antenna that is parallel to the plane defined by the horizon.

Most cells are divided into a plurality of “sectors,” and separate base station antennas provide coverage (service) to each of the sectors. The most common base station configuration is the so-called “three sector configuration” in which a cell is divided into three 120° “sectors” in the azimuth plane. In a three sector configuration, the antenna beams generated by the linear arrays typically have half power beamwidths in the azimuth plane (“azimuth HPBW”) of about 65° (i.e., the angle subtended in the azimuth plane by the portion of the antenna beam that has a gain that is within 3 dB of the peak gain is about 65°). Generally speaking, an antenna beam having an azimuth HPBW of about 65° will provide reasonably good coverage throughout a 120° sector without having excessive spillover of RF energy into adjacent sectors. Such spillover of RF energy into adjacent cells is undesirable both because it reduces the gain of the antenna beam within the sector and because the spillover appears as interference to the antenna beams in the adjacent sectors.

Typically, each base station antenna will include multiple linear arrays of radiating elements that operate, for example, using second generation (“2G”), third generation (“3G”) or fourth generation (“4G”) cellular network protocols. The linear arrays may be “perfect” columns of radiating elements where all of the radiating elements are aligned along a vertically-extending axis, or may be “staggered” columns in which some of the radiating elements are staggered horizontally (and may even be aligned with an adjacent column of radiating elements) in order to reduce (narrow) the azimuth HPBW of the antenna beams generated by the linear arrays. Most modern base station antennas include both “low-band” linear arrays of radiating elements that support service in some or all of the 617-960 MHz frequency band and “mid-band” linear arrays of radiating elements that support service in some or all of the 1427-2690 MHz frequency band. These linear arrays are typically formed using dual-polarized radiating elements, which allows each linear array to transmit and receive RF signals at two orthogonal polarizations.

The radiating elements of each of the above-described linear arrays are coupled to two ports of a radio (one port for each polarization). An RF signal that is to be transmitted by a linear array is passed from the radio port to the antenna where it is divided into a plurality of sub-components, with each sub-component fed to a respective subset of the radiating elements in the linear array (typically each sub-component is fed to between one and three radiating elements). The sub-components of the RF signal are transmitted through the radiating elements to generate an antenna beam that covers a generally fixed coverage area, such as a sector of a cell. Since the antenna beams generated by the above-described 2G/3G/4G linear arrays generate fixed (static) antenna beams, they are often referred to as “passive” linear arrays.

Most cellular operators are currently upgrading their networks to support fifth generation (“5G”) cellular service. One important component of 5G cellular service is the use of so-called “active” beamforming arrays that operate in conjunction with “active” beamforming radios to dynamically adjust the size, shape and pointing direction of the antenna beams that are generated by the active beamforming array. Active beamforming arrays are typically formed using “high-band” radiating elements that operate in higher frequency bands, such as some or all of the 3.1-4.2 GHz and/or the 5.1-5.8 GHz frequency bands, although active beamforming arrays may also be provided that operate in the upper portion of the mid-band frequency range (e.g., 2300-2690 MHz). Many modern base station antennas include both passive low-band and mid-band linear arrays plus one or more 5G beamforming arrays. Moreover, in order to support higher order multi-input-multi-output (“MIMO”) communication techniques (e.g., 4xMIMO or 8xMIMO) and/or to provide service in multiple sub-bands of the mid-band frequency range, many base station antennas include multiple (e.g., two or four) low-band and/or mid-band linear arrays.

In order to fit larger numbers of arrays in a base station antenna, the radiating elements of the mid-band and/or high-band arrays are often mounted behind the radiating elements of the low-band linear arrays. Unfortunately, the low-band radiating elements can cause scattering of the RF energy emitted by the higher frequency band (mid-band or high-band) radiating elements. Scattering is undesirable as it changes the shape of the antenna beams generated by the higher frequency band array in both the azimuth and elevation planes. Scattering tends to increase the azimuth and elevation beamwidths of the higher frequency band antenna beams, which acts to reduce the gain, degrade the front-to-back ratio, and/or increase the interference that the antenna beams generate in neighboring sectors.

The scattering may occur because conductive structures of the low-band radiating elements can reflect RF energy transmitted by the higher frequency band radiating elements, causing the higher band RF energy to exit the base station antenna in undesired directions and/or in a desired direction but with a phase that causes the reflected RF energy to destructively combine with non-reflected RF energy. Scattering may also occur because certain conductive structure of the low-band radiating elements may have electrical lengths that make the structure resonant in the operating frequency band of the higher frequency band array, which may occur if the conductive structure has an electrical length that is about ½ a wavelength or about a full wavelength of a frequency within the operating frequency band of the higher frequency band array. Since the mid-band operating frequency range includes frequencies that are twice certain frequencies in the low-band operating frequency range, and the high-band operating frequency range includes frequencies that are four times certain frequencies in the low-band operating frequency range, the dipole arms of the low-band radiating elements—which typically have an electrical length of about ¼ of a center wavelength of the low-band operating frequency range—are typically resonant in at least portions of both the mid-band and high-band operating frequency ranges. When the low-band dipole arms are resonant in either the mid-band or the high-band, RF energy transmitted by the higher frequency band array may couple to the dipole arms of nearby low-band radiating elements and then re-radiate therefrom, resulting again in the higher frequency band RF exiting the base station antenna in undesired directions and/or to destructively combining with other RF energy emitted by the higher frequency band array.

“Cloaking” dipole radiating elements are known in the art that have dipole arms that are designed so that currents will largely not form thereon in response to RF radiation in pre-selected frequency ranges (e.g., currents in the operating frequency band of the high-band radiating elements in the 5G beamforming array). These radiating elements can reduce or eliminate the second of the above-described types of scattering of higher frequency band radiation by the dipole arms of nearby lower frequency band radiating elements.

While there is commercial interest in base station antennas that have many different arrays of radiating elements, cost is a major concern for cellular network operators and hence cellular network operators may not always deploy base station antennas that maximize performance in order to reduce cost. In addition, cellular network operators also often have strict limits on the widths of various types of base station antennas. Base station antennas are often mounted on antenna towers hundreds of feet above the ground and can be subject to very high wind levels. As a base station antenna is made wider, the wind loading increases, requiring that the base station antenna, its mounting hardware, and the antenna tower itself have increased structural durability. Thus, as the number of arrays included in a base station antenna is increased, the spacing between the arrays typically must be decreased to keep the width of the antenna within cellular network operator specified limits. Unfortunately, as the spacing between arrays is decreased, the adjacent arrays tend to interact with each other in undesirable ways, which can degrade the performance of the base station antenna. Thus, there is a need for low cost base station antennas that support a wide variety of services while also fitting within cellular network operator expectations for the width of the base station antenna.

### SUMMARY

Pursuant to some embodiments of the present invention, radiating elements that are suitable for use in base station antennas are provided that comprise a dielectric support, first through fourth sheet metal dipole arms on the dielectric support, and a feed stalk printed circuit board. The feed stalk printed circuit board includes a first RF transmission line that has a first signal conductor that is coupled to the first sheet metal dipole arm through at least a first capacitive connection and a first ground conductor that is coupled to the second sheet metal dipole arm through at least a second capacitive connection and a second RF transmission line that has a second signal conductor that is coupled to the third sheet metal dipole arm through at least a third capacitive connection and a second ground conductor that is coupled to the fourth sheet metal dipole arm through at least a fourth capacitive connection.

In some embodiments, the radiating element may further comprise a coupling printed circuit board that is mounted on the feed stalk printed circuit board. The coupling printed circuit board may include a first metal pad that is electrically connected to the first signal conductor through a first galvanic connection, a second metal pad that is electrically connected to the first ground conductor through a second galvanic connection, a third metal pad that is electrically connected to the second signal conductor through a third galvanic connection, and a fourth metal pad that is electrically connected to the second ground conductor through a fourth galvanic connection. In some embodiments, the first metal pad is capacitively coupled to the first sheet metal dipole arm, the second metal pad is capacitively coupled to the second sheet metal dipole arm, the third metal pad is capacitively coupled to the third sheet metal dipole arm, and the fourth metal pad is capacitively coupled to the fourth sheet metal dipole arm. In some embodiments, a base of the feed stalk printed circuit board that is remote from the dipole arms is positioned rearwardly of the first through fourth sheet metal dipole arms and the coupling printed circuit board is positioned forwardly of the first through fourth sheet metal dipole arms. In some embodiments, the first through fourth sheet metal dipole arms are positioned in between the dielectric support and the coupling printed circuit board. In some embodiments, the first through fourth metal pads are on a forward surface of a dielectric substrate of the coupling printed circuit board.

In some embodiments, the first ground conductor may include a first meandered trace segment and the second ground conductor includes a second meandered trace segment. In some embodiments, the first meandered trace segment and the second capacitive connection together form a first capacitor-inductor circuit that increases an impedance of the first RF transmission line, and the second meandered trace segment and the fourth capacitive connection together form a second capacitor-inductor circuit that increases an impedance of the second RF transmission line.

In some embodiments, a distal end of the feed stalk printed circuit board that is opposite the base may extend through a slot in the coupling printed circuit board.

In some embodiments, each of the first through fourth sheet metal dipole arms may be positioned adjacent two other of the first through fourth sheet metal dipole arms so that together the first through fourth sheet metal dipole arms form a radiating surface that has a square perimeter. In such embodiments, the feed stalk printed circuit board extends through an opening in the center of the radiating surface.

In some embodiments, the first signal conductor may be coupled to the first sheet metal dipole arm through both a solder joint and the first capacitive connection.

In some embodiments, the first sheet metal dipole arm includes a first tab that extends parallel to the feed stalk printed circuit board and is configured to capacitively couple with the first signal conductor to form the first capacitive connection, the second sheet metal dipole arm includes a second tab that extends parallel to the feed stalk printed circuit board and is configured to capacitively couple with the first ground conductor to form the second capacitive connection, the third sheet metal dipole arm includes a third tab that extends parallel to the feed stalk printed circuit board and is configured to capacitively couple with the second signal conductor to form the third capacitive connection, and the fourth sheet metal dipole arm includes a fourth tab that extends parallel to the feed stalk printed circuit board and is configured to capacitively couple with the second ground conductor to form the fourth capacitive connection. In such embodiments, the radiating element may further comprise a first solder mask on a first side of the feed stalk printed circuit board that is positioned between the first tab and the first signal conductor and a second solder mask on a second side of the feed stalk printed circuit board that is positioned between the second tab and the first ground conductor. In some embodiments, one of the first and second solder masks may also be positioned between the third tab and the second signal conductor and the other of the first and second solder masks is positioned between the fourth tab and the second ground conductor.

Pursuant to some embodiments of the present invention, radiating elements that are suitable for use in base station antennas are provided that comprise a plurality of sheet metal dipole arms, a feed stalk printed circuit board, and a coupling printed circuit board that is mounted on the feed stalk printed circuit board and configured to capacitively couple RF signals between the feed stalk printed circuit board and the sheet metal dipole arms.

In some embodiments, a base of the feed stalk printed circuit board is positioned rearwardly of the dipole arms and the coupling printed circuit board is positioned forwardly of the dipole arms.

In some embodiments, the first and second conductors of a first RF transmission line of the feed stalk printed circuit board are galvanically connected to respective first and second metal pads on the coupling printed circuit board.

In some embodiments, the first and second metal pads are on a forward surface of a dielectric substrate of the coupling printed circuit board.

In some embodiments, the first RF transmission line of the feed stalk printed circuit board includes a meandered trace segment. In such embodiments, the meandered trace segment and a capacitive connection between the first metal pad on the coupling printed circuit board and a first of the dipole arms may together form a capacitor-inductor circuit that increases an impedance of the first RF transmission line.

In some embodiments, the feed stalk printed circuit board comprises a first RF transmission line that is coupled to first and second of the sheet metal dipole arms and a second RF transmission line that is coupled to third and fourth of the sheet metal dipole arms.

In some embodiments, the coupling printed circuit board includes a first metal pad that is galvanically connected to a signal conductor of the first RF transmission line, a second metal pad that is galvanically connected to a ground conductor of the first RF transmission line, a third metal pad that is galvanically connected to a signal conductor of the second RF transmission line, and a fourth metal pad that is galvanically connected to a ground conductor of the second RF transmission line.

In some embodiments, the plurality of sheet metal dipole arms comprises first through fourth sheet metal dipole arms, and the first through fourth metal pads are capacitively coupled to respective ones of first through fourth sheet metal dipole arms.

In some embodiments, the feed stalk printed circuit board includes at least one tab that extends through a slot in the coupling printed circuit board.

Pursuant to still further embodiments of the present invention, radiating elements that are suitable for use in base station antennas are provided that comprise a dielectric support, a first sheet metal dipole arm on the dielectric support, a second sheet metal dipole arm on the dielectric support, and a feed stalk printed circuit board that includes a first RF transmission line that includes a first signal conductor and a first ground conductor. The first sheet metal dipole arm includes a first tab that is configured to capacitively couple with the first signal conductor and the second sheet metal dipole arm includes a second tab is configured to capacitively couple with the first ground conductor.

In some embodiments, the first and second tabs extend parallel to the feed stalk printed circuit board.

In some embodiments, the radiating element may further comprise a first solder mask on a first side of the feed stalk printed circuit board that is positioned between the first tab and the first signal conductor and a second solder mask on a second side of the feed stalk printed circuit board that is positioned between the second tab and the first ground conductor.

In some embodiments, the feed stalk printed circuit board further comprises a second RF transmission line that includes a second signal conductor and a second ground conductor, and the radiating element further comprises a third sheet metal dipole arm and a fourth sheet metal dipole arm.

In some embodiments, the third sheet metal dipole arm includes a third tab that extends parallel to the feed stalk printed circuit board and is configured to capacitively couple with the second signal conductor and the fourth sheet metal dipole arm includes a fourth tab that extends parallel to the feed stalk printed circuit board and is configured to capacitively couple with the second ground conductor.

In some embodiments, the first solder mask is also positioned between the third tab and the second signal conductor and the second solder mask is positioned between the fourth tab and the second ground conductor.

In some embodiments, the first RF transmission line includes a meandered trace segment. In some embodiments, the meandered trace segment and a capacitive connection between the first pad and the first signal conductor together form a capacitor-inductor circuit that increases an impedance of the first RF transmission line.

### BRIEF DESCRIPTION OF THE DRAWINGS

FIG. 1 is an exploded front perspective view of a conventional low-band radiating element.

FIG. 2A is a perspective view of a conventional multiband base station antenna.

FIG. 2B is a schematic front view of the conventional base station antenna of FIG. 2A with the radome removed that illustrates an antenna assembly of the antenna.

FIG. 3A is a front perspective view of a low-band radiating element according to embodiments of the present invention.

FIG. 3B is a side view illustrating a first major surface of the feed stalk printed circuit board included in the radiating element of FIG. 3A.

FIG. 3C is a side view illustrating a second major surface of the feed stalk printed circuit board included in the radiating element of FIG. 3A.

FIG. 3D is a front view of the four dipole arms included in the radiating element of FIG. 3A.

FIG. 3E is a front view illustrating a first major surface of a coupling printed circuit board included in the radiating element of FIG. 3A.

FIGS. 4A-4C are front views illustrating first major surfaces of three alternative coupling printed circuit boards that may be used in place of the coupling printed circuit board of FIG. 3E in the radiating element of FIG. 3A.

FIG. 4D is a shadow front view of another alternative coupling printed circuit board that may be used in place of the coupling printed circuit board of FIG. 3E in the radiating element of FIG. 3A.

FIG. 5A is a front perspective view of a low-band radiating element according to further embodiments of the present invention.

FIG. 5B is an enlarged perspective front view of the electrical connections between the feed stalk printed circuit board and dipole arms of the low-band radiating element of FIG. 5A.

### DETAILED DESCRIPTION

The size of a radiating element is generally inversely-correlated with frequency and therefore the low-band radiating elements are typically the largest radiating elements in a base station antenna. Most cellular operators prefer base station antennas that include at least two low-band linear arrays (to support 4xMIMO communications) because low-band RF signals pass more readily through physical obstacles such as trees, buildings, hills, etc. than do mid-band and high-band RF signals.

Conventional low-band radiating elements typically have a “footprint” of nearly 140 mm×140 mm, where the footprint refers to the size of the radiating element when viewed from the front. Since two linear arrays of low-band radiating elements need to be spaced apart from each other by some distance (e.g., at least 215 mm center-to-center) and since the low-band radiating elements also need to be inset from the sides of the base station antenna, the large physical size of conventional low-band radiating elements made it difficult to fabricate base station antennas that include two low-band linear arrays that had widths of less than 450 mm. PCT Patent Publication No. WO 2023/192929 (“the '929 publication”) discloses several low-band radiating element designs where the radiating elements have a footprint of less than 130 mm×130 mm. Using the smaller low-band radiating elements of the '929 publication, base station antennas can be provided that have two linear arrays of low-band radiating elements where the width of the base station antenna is less than 400 mm.

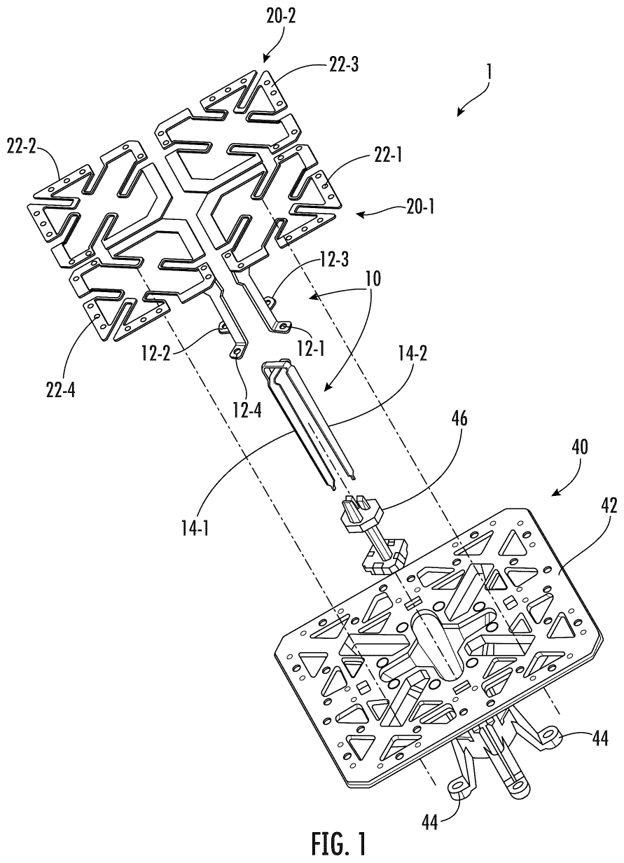

FIG. 1 is an exploded perspective view of the small footprint low-band radiating element 1 that is disclosed in the '929 publication. As shown in FIG. 1, the radiating element 1 is a so-called cross-dipole radiating element that includes first and second dipole radiators 20-1, 20-2 that are perpendicular to each other. The dipole radiators 20 are arranged so that the first dipole radiator 20-1 extends at an angle of −45° with respect to a longitudinal axis of a base station antenna that includes radiating element 1, while the second dipole radiator 20-2 extends at an angle of +45° with respect to a longitudinal axis of the base station antenna. Thus, the first dipole radiator 20-1 will emit RF radiation having a linear slant −45° polarization, while the second dipole radiator 20-2 will emit RF radiation having a linear slant +45° polarization. These two polarizations are orthogonal to each other and hence radiating element 1 can simultaneously transmit/receive two RF signals at the same frequency because of the inherent isolation between the two polarizations. It should be noted that herein like elements may be referred to individually by their full reference numeral (e.g., second dipole radiator 20-2) and may be referred to collectively by the first part of their reference numeral (e.g., the dipole radiators 20).

The first dipole radiator 20-1 comprises first and second dipole arms 22-1, 22-2, while the second dipole radiator 20-2 comprises third and fourth dipole arms 22-3, 22-4. Radiating element 1 further includes a feed stalk 10 in the form of first through fourth dipole legs 12-1 through 12-4, which are electrically connected to the respective first through fourth dipole arms 22-1 through 22-4. Each dipole leg 12 and its associated dipole arm 22 are formed as an integral (monolithic) clement by stamping the clement from sheet metal and then bending the stamped sheet metal into the shape shown in FIG. 1. The dipole legs 12 are typically mounted on a reflector of a base station antenna (or on a feed board printed circuit board that is mounted on the reflector) and extend generally perpendicularly to the dipole arms 22. Consequently, the dipole legs 12 may mount the dipole arms 22 forwardly of the reflector and extending generally parallel to the reflector.

Radiating element 1 may be connected to first and second RF transmission lines of respective first and second feed networks of the base station antenna in which radiating element 1 is used. Most typically, the first and second RF transmission lines of these feed networks are provided on a feed board printed circuit board that the radiating element 1 is mounted on. However, other implementations are possible (e.g., radiating element 1 may be directly fed by first and second coaxial cables that form the first and second RF transmission lines). The ground conductor of the first RF transmission line may be connected to the first and second dipole legs 12-1, 12-2, and the ground conductor of the second RF transmission line may be connected to the third and fourth dipole legs 12-3, 12-4.

The feed stalk 10 further includes first and second feed lines 14-1, 14-2 that feed the respective first and second dipole radiators 20-1, 20-2. Each feed line 14 includes a base that is adjacent the reflector of the base station antenna and that connects to a respective one of the first and second RF transmission lines (i.e., to the feed networks). Each feed line 14 also has a distal end that is adjacent the dipole arms 22. Each feed line 14 is formed of stamped and bent sheet metal, and takes the form of a respective hook-balun. As is well known in the art, a hook-balun feed line may be used to capacitively feed the two dipole arms that form a dipole radiator. The dipole legs 12 define a rectangular cylinder and the feed lines 14 extend through this rectangular cylinder so that the dipole legs 12 surround the feed lines 14. The forwardly and rearwardly portions of the hook-balun feed lines 14 extend parallel to the dipole legs 12 and perpendicularly to the dipole arms 22. Each of the first through fourth dipole arms 22 is positioned adjacent two other of the first through fourth dipole arms 22 to form a radiating surface 24 that has a square perimeter when viewed from the front. Each dipole arm 22 may have a perimeter that generally defines a square, except that one corner of the perimeter is truncated so that an opening 26 is provided in the middle of the radiating surface 24. The distal ends of the feed lines 14 are mounted through or behind this opening 26.

The dipole arms 22 are mounted on a dielectric support 40. The dielectric support 40 includes a forward supporting surface 42 that has a substantially square outer contour. The four dipole arms 22-1 through 22-4 are mounted on and supported by the forward supporting surface 42 of dielectric support 40 and may be attached to the dielectric support 40 using fastening elements such as rivets or a dielectric cover. The dielectric support 40 further includes a plurality of rearwardly extending legs 44 that may be mounted, for example, on a reflector of a base station antenna. A separate dielectric feed line support 46 is provided that mounts the feed lines 14 in the rectangular cylinder defined by the dipole legs 12.

Still referring to FIG. 1, each sheet metal dipole arm 22 has an outer contour that generally has a square shape, and the four sheet metal dipole arms 22-1 through 22-4 are positioned next to each other so that the outer contour of the combination of all four dipole arms 22-1 through 22-4 defines a larger radiating surface that has a generally square outer perimeter. The first and second inner sides of each dipole arm 22 are adjacent inner sides of two others of the dipole arms 22. Adjacent dipole arms 22 are separated by a small gap so that the larger radiating surface defined by the combination of all four dipole arms 22 is more than four times larger than the smaller squares defined by the individual dipole arms 22.

Each dipole arm 22 includes a plurality of wide sections 30 and a plurality of narrowed sections 32, in which, every two adjacent wide sections 30 are connected through a narrowed section 32. The widened sections 30 may capacitively couple with each other and the narrowed sections 32 may add inductance so that the dipole arms 22 may have embedded inductor-capacitor (“LC”) circuits that may be tuned to pass lower frequency band currents while blocking higher frequency band currents. As a result, the dipole arms 22 may readily transmit and receive RF signals in the low-band operating frequency range while being substantially transparent to RF energy in the mid-band and/or high-band operating frequency ranges. In other words, the low-band radiating clement 1 may be cloaked with respect to mid-band and/or high-band RF radiation so that such radiation will not induce substantial currents on the low-band dipole arms 22.

As discussed in the '929 publication, the radiating element 1 may be designed to operate on the 696-960 MHz frequency band and may have a footprint of only 126 mm×126 mm, which is significantly smaller than most other conventional low-band radiating elements. This may allow the width of a base station antenna that includes two linear arrays of low-band radiating elements to be reduced. In addition, since the size of the low-band radiating element 1 is reduced in both the horizontal and vertical directions, the low-band radiating element 1 may have less overlap with the mid-band and/or high-band radiating elements when used in a multi-band base station antenna, which can further improve the cloaking performance.

Pursuant to embodiments of the present invention, small low-band radiating elements are provided that may exhibit good cloaking performance and have reduced cost. The radiating elements 1 of the '929 publication may be less expensive than low-band radiating elements in which the dipole arms and feed stalks are formed on printed circuit boards, since sheet metal dipole arms and legs may be significantly cheaper than the relatively large printed circuit boards required to implement the dipole radiators and feed stalks of low-band radiating elements. However, conventional printed circuit board based radiating elements may have some advantages as compared to the sheet metal radiating elements 1 of the '929 publication in that printed circuit board based feed stalks may be easy to mount on the feed board printed circuit boards of a base station antenna, and also can be readily soldered to feed board printed circuit boards to electrically connect the RF transmission lines on the feed board printed circuit boards to corresponding RF transmission lines on the feed stalk printed circuit boards. The dipole legs 12 and feed lines 14 of the above-described sheet metal radiating element 1 of the '929 publication are also typically soldered to a feed board printed circuit board of a base station antenna. However, to ensure a good solder joint that will not introduce passive intermodulation distortion, a tin-based material is plated on the dipole arms and legs 12, 14 of the radiating element 1. This tin plating process increases the cost of the radiating element 1. In addition, the four dipole legs 12 and two hook balun feed lines 14 may comprise a significant amount of metal that may scatter RF radiation emitted by higher band radiating elements that are mounted rearwardly of the radiating elements 1 (i.e., the radiating element 1, even though cloaked to suppress the second type of scattering discussed above, may still cause the first type of scattering). As discussed above, such scattering may degrade the shape, pointing direction, gain and other parameters of the antenna beams generated by arrays of higher band radiating elements that are mounted rearwardly of a linear array of low-band radiating elements 1.

The radiating elements according to embodiments of the present invention may include inexpensive sheet metal based dipole arms that are fed by a printed circuit board based feed stalk. Each electrical connection between the feed stalk and the dipole arms may comprise a capacitive connection, which eliminates any need to solder the dipole arms to the feed stalk, thereby eliminating any need to plate a tin-based material on the sheet metal dipole arms. In addition, the feed stalks for the radiating elements according to embodiments of the present invention may be implemented using a single, relatively small feed stalk printed circuit board, which further reduces the cost of the radiating element and also reduces the extent to which the feed stalk scatters RF radiating emitted by nearby higher band radiating elements.

In some cases, the radiating elements according to embodiments of the present invention may include a small coupling printed circuit board that may be mounted, for example, forwardly of the dipole arms. In such embodiments, the feed stalk printed circuit board may extend through an opening in the radiating surface defined by the dipole arms so that the coupling printed circuit board may be mounted on the distal end of the feed stalk printed circuit board. The feed stalk printed circuit board may include one or more forwardly extending tabs that extend through corresponding slots in the coupling printed circuit board to mechanically mount the coupling printed circuit board on the feed stalk printed circuit board. Solder joints may be applied to improve the mechanical connection between the coupling printed circuit board and the feed stalk printed circuit board and to electrically connect the signal and ground conductors of first and second RF transmission lines on the on the feed stalk printed circuit board to four corresponding metal pads on the coupling printed circuit board. The four metal pads on the coupling printed circuit board may be capacitively coupled to respective ones of the four dipole arms. Thus, the signal and ground conductors of the RF transmission lines on the feed stalk printed circuit board may be coupled to the respective dipole arms through both a galvanic (solder joint) connection and a capacitive connection. The coupling printed circuit board may be very small, and hence may not materially add to the expense of the radiating element.

In other embodiments, the radiating elements may be designed so that the signal and ground conductors of first and second RF transmission lines on the feed stalk printed circuit board may be connected to respective ones of the four dipole arms through “direct” capacitive connections. In example embodiments, each sheet metal dipole arm may include a tab that is bent to extend substantially in parallel to the feed stalk printed circuit board, where each tab is positioned to horizontally overlap a respective one of the signal and ground conductors of the RF transmission lines on the feed stalk printed circuit board. One or more solder masks may be interposed between the tabs and the respective conductors so that each tab and its associated conductor forms a capacitor so that the signal and ground conductors of the RF transmission lines on the feed stalk printed circuit board are capacitively coupled to the respective dipole arms. Using such direct capacitive connections eliminates any need for a coupling printed circuit board, further reducing the cost of the radiating element.

The dipole arms of the radiating elements according to embodiments of the present invention may be cloaked dipole arms that are designed to suppress the formation of currents on the dipole arms in certain higher frequency bands. While the use of cloaking dipole arms may improve the performance of a multiband base station antenna, the cloaking design often increases the impedance of the dipole arms above 50 ohms such that the dipole arms may not have a good impedance match with the feed stalk printed circuit board (typically the RF lines on a feed stalk printed circuit board are designed as 50 ohm RF transmission lines in order to be impedance matched with the RF transmission lines of a feed network that feeds the feed stalks). The feed stalk printed circuit boards used in the radiating elements according to embodiments of the present invention may include inductive elements such as meandered traces that, in conjunction with the capacitive connections to the dipole arms, may form impedance matching circuits that better match the RF transmission lines on the feed stalk printed circuit board to the dipole arms, thereby expanding the operating bandwidth of the radiating elements.

Before discussing the radiating elements according to embodiments of the present invention it is helpful to discuss the design of an example conventional multiband base station antenna.

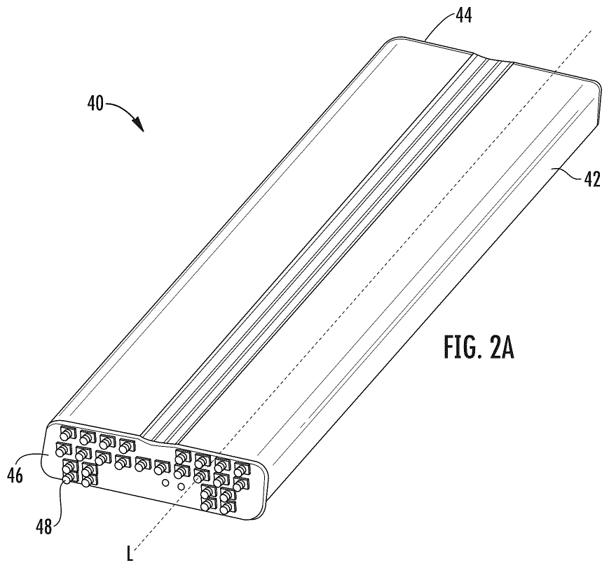

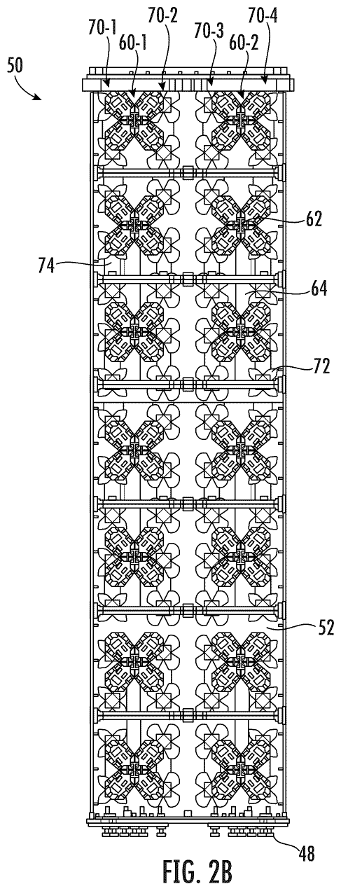

FIG. 2A is a schematic front view of a conventional multiband base station antenna 40. In the description that follows, the base station antenna 40 and the radiating elements included therein will be described using terms that assume that the base station antenna 40 is mounted for normal use on a tower with a longitudinal axis of the base station antenna 40 extending along a vertical axis and the front surface of the base station antenna 40 mounted opposite the tower (or other mounting structure) so as to point toward the coverage area for the base station antenna 40.

As shown in FIG. 2A, the conventional base station antenna 40 is an elongated structure that extends along a longitudinal axis. The base station antenna 40 may have a tubular shape with a generally rectangular cross-section. The base station antenna 40 includes a tubular radome 42 and a top end cap 44. The base station antenna 40 also includes a bottom end cap 46 which includes a plurality of RF ports 48 such as RF connectors mounted therein. The RF ports 48 extend through the bottom end cap 46. The radome 42, top cap 44 and bottom cap 46 may form an external housing for the antenna 40. An antenna assembly 50 (FIG. 2B) is contained within the external housing. The antenna assembly 50 may be slidably inserted into the radome 42 from either the top or bottom before the top end cap 44 or bottom end cap 46 are attached to the radome 42.

FIG. 2B is a schematic perspective view of the antenna assembly 50 of base station antenna 40. As shown in FIG. 2B, the antenna assembly 50 includes a reflector 52 which may comprise a metallic surface (e.g., a sheet of aluminium) that reflects forwardly RF radiation that is emitted rearwardly by the radiating elements included in the base station antenna 40 and which also serves as a ground plane for the radiating elements. Various mechanical and electronic components of the antenna (not shown) may be mounted behind the reflector 52 such as, for example, phase shifters, remote electronic tilt units, mechanical linkages, controllers, diplexers, and the like.

A plurality of linear arrays of dual-polarized radiating elements are mounted to extend forwardly from the reflector 52. The linear arrays include two low-band linear arrays 60-1, 60-2 that each comprise a respective vertically-extending column of low-band radiating elements 62, and four mid-band linear arrays 70-1 through 70-4 that each comprise a respective vertically-extending column of mid-band radiating elements 72. The base station antenna 40 is often referred to as a 2L4H antenna, reflecting that the antenna 40 includes two low-band linear arrays 60 and four higher-band (here mid-band) linear arrays 70. The RF ports 48 are used to connect the linear arrays 60, 70 to one or more external radios (not shown).

In the depicted embodiment, the first low-band linear array 60-1 is positioned between the first and second mid-band linear arrays 70-1, 70-2, and the second low-band linear array 60-2 is positioned between the third and fourth mid-band linear arrays 70-3, 70-4. It will be appreciated that base station antenna 40 illustrates one typical layout of arrays of low-band and mid-band linear arrays 60, 70. It will likewise be appreciated that the number and/or types of arrays may be varied from what is shown based on applications and/or customer requirements, as may the positioning of the linear arrays on the reflector 52 and/or the number of radiating elements included in each linear array. For example, the base station antenna 40 could alternatively include one or more planar arrays of high-band radiating elements that replace the second and third linear arrays 70-2, 70-3 of mid-band radiating elements 72.

The low-band radiating elements 62 may be configured to transmit and receive signals in a first frequency band such as, for example, the 617-960 MHz frequency range or a portion thereof (and most typically, in the 696-960 MHz frequency band). The mid-band radiating elements 72 may be configured to transmit and receive signals in a second frequency band such as, for example, the 1427-2690 MHz frequency range or a portion thereof. In the depicted embodiment, the mid-band radiating elements in linear arrays 70-1 and 70-4 include mid-band radiating elements that are configured to transmit and receive RF signals in the 1695-2690 MHz frequency band, while the mid-band radiating elements in linear arrays 70-2 and 70-3 include mid-band radiating elements that are configured to transmit and receive RF signals in the 1427-2690 MHz frequency band. The radiating elements 62, 72 may be dual polarized radiating elements (e.g., −45°/+45° cross-dipole radiating elements), and hence each linear array 60, 70 may be used to form a pair of antenna beams, namely an antenna beam for each of the two polarizations at which the dual-polarized radiating elements 62, 72 are designed to transmit and receive RF signals. The radiating elements 62, 72 are mounted on feed board printed circuit boards (herein “feedboards”) 64, 74 that couple RF signals to and from the individual radiating elements 62, 72. One or more radiating elements 62, 72 may be mounted on each feedboard 64, 74. Cables (not shown) may be used to connect each feed board printed circuit board to other components of the antenna such as diplexers, phase shifters or the like.

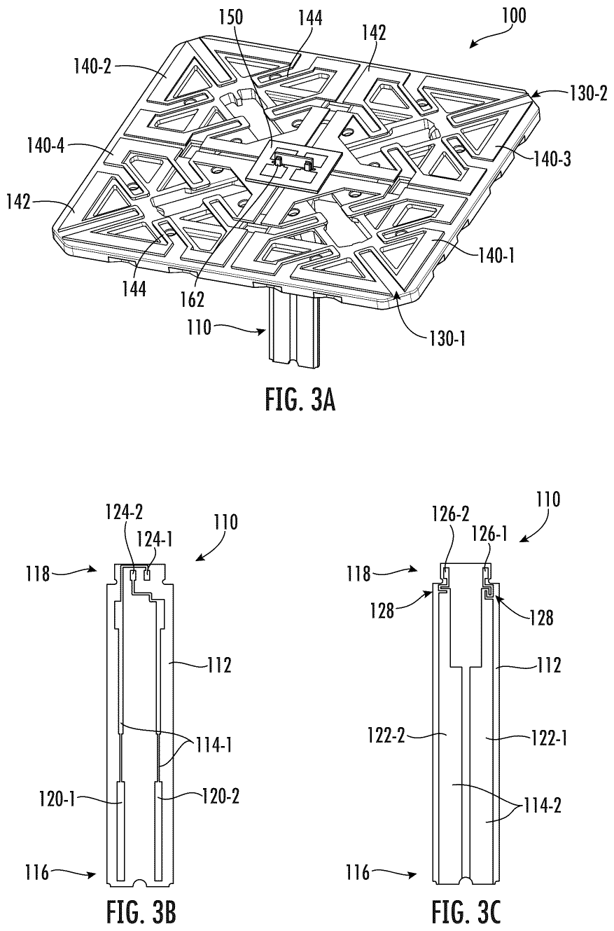

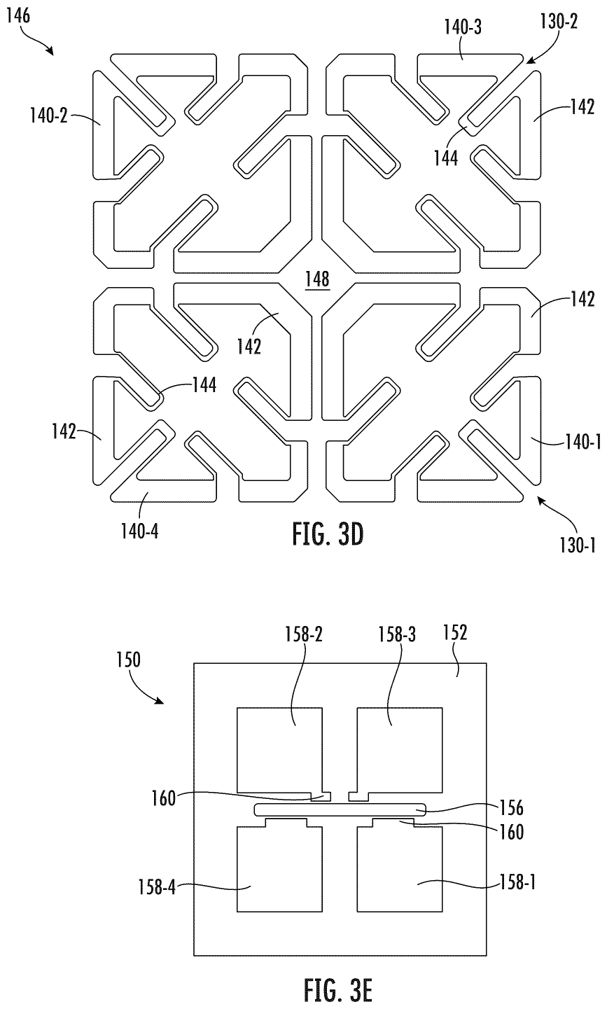

FIGS. 3A-3E illustrate a low cost, cloaked, cross-dipole low-band radiating element 100 according to embodiments of the present invention. In particular, FIG. 3A is a schematic front perspective view of the low-band radiating element 100. FIGS. 3B and 3C are side views illustrating the first and second major surfaces, respectively, of the feed stalk printed circuit board included in the radiating element 100. FIG. 3D is a front view of the four dipole arms included in the radiating element 100. Finally, FIG. 3E is a front view illustrating a first major surface of a coupling printed circuit board included in the radiating element 100. The low-band radiating element 100 may, for example, be used in place of some or all of the low-band radiating elements 62 that are included in the base station antenna 40 of FIGS. 2A-2B to provide a base station antenna according to embodiments of the present invention. The base station antennas according to embodiments of the present invention may be used, for example, as sector base station antennas in the above-described base stations of a cellular communications network. As shown in FIG. 3A, the low-band radiating element 100 includes a feed stalk printed circuit board 110, first and second dipole radiators 130-1, 130-2, a coupling printed circuit board 150, and a dielectric support 170.

Referring to FIGS. 3B-3C, the feed stalk printed circuit board 110 comprises a single printed circuit board. The feed stalk printed circuit board 110 includes a dielectric substrate 112 that has a first metallization pattern 114-1 (FIG. 3B) on a first major surface thereof and a second metallization pattern 114-2 (FIG. 3C) on a second major surface thereof that is opposite the first major surface of the dielectric substrate 112. The feed stalk printed circuit board 110 includes a base 116 that may be mounted, for example, on a feed board printed circuit board (not shown) and a distal end 118 that is opposite the base 116.

The rear portions of the feed stalk printed circuit board 110 includes small rearwardly projecting tabs. These projecting tabs may be inserted through slits in a feedboard (e.g., one of the feedboards 64 of FIG. 2B) in order to mount the radiating element 100 on the feedboard 64. The feed stalk printed circuit board 110 includes first and second signal conductors 120-1, 120-2 and first and second ground conductors 122-1, 122-2. The first signal conductor 120-1 overlaps the first ground conductor 122-1 and together the first signal conductor 120-1 and the first ground conductor 122-1 form a first feed line, which is in the form of a microstrip RF transmission line. The second signal conductor 120-2 similarly overlaps the second ground conductor 122-2 and together the second signal conductor 120-2 and the second ground conductor 122-2 form a second feed line, which is also in the form of a microstrip RF transmission line. Each rearwardly projecting tab may include a metallized portion and solder joints may be applied so that the first and second signal conductors 120-1, 120-2 are electrically connected to first and second signal traces of RF transmission lines on the feedboard 64 and so that the first and second ground conductors 122-1, 122-2 are electrically connected to first and second ground lines of RF transmission lines on the feedboard 64. In this fashion the feed stalk printed circuit board 110 may be mechanically mounted on a feedboard 64 and a pair of RF transmission lines on the feedboard 64 may be electrically connected to the first and second feed lines 120-1/122-1; 120-2/122-2 that are provided on the feed stalk printed circuit board 110. The radiating clement 100 may be mounted to extend forwardly from the feedboard 64 with the feed stalk printed circuit board 110 extending perpendicularly to the feedboard 64.

As shown in FIGS. 3B-3C, the first and second signal conductors 120-1, 120-2 are part of the first metallization pattern 114-1 on the first major surface of the dielectric substrate 112. Each signal conductor 120 is implemented as an elongated metal trace that extends from the base 116 to the distal end 118 of the feed stalk printed circuit board 110. Each elongated trace has portions that have different widths. The widths may be selected so that the first and second feed lines 120-1/122-1; 120-2/122-2 that are provided on the feed stalk printed circuit board 110 will have a desired impedance. The distal ends of the traces that form the signal conductors 120 may be widened to form metal pads 124-1, 124-2. The function of the metal pads 124 will be discussed below.

The first and second ground conductors 122-1, 122-2 are part of the second metallization pattern 114-2 on the second major surface of the dielectric substrate 112. Each ground conductor 122 is implemented as a widened metal trace that extends from the base 116 to the distal end 118 of the feed stalk printed circuit board 110. Forward portions of each widened trace may have smaller widths than the portions of the ground conductors 122 that are adjacent the base of the feed stalk printed circuit board 110. The distal end of the traces that form the ground conductors 122 may be widened to form metal pads 126-1, 126-2. The function of the metal pads 126 will be discussed below. In addition, each ground conductor 122 may include a section where the width of the ground conductor 122 is made small (e.g., no more than one-fourth the width of the widest part of the ground conductor 122) to form a narrow trace section 128 that has increased inductance The narrow trace section 128 may be a meandered trace section. By meandering the trace, an inductance of the narrow trace section 128 may be further increased. Thus, each narrowed trace section 128 may form an inductor.

Referring to FIGS. 3A and 3D, the first dipole radiator 130-1 includes first and second sheet metal dipole arms 140-1, 140-2 that extend collinearly so that the first dipole radiator 130-1 will extend at an angle of −45° with respect to the horizon when the radiating element 100 is mounted for use in a base station antenna. The second dipole radiator 130-2 includes third and fourth sheet metal dipole arms 140-3, 140-4 that extend collinearly so that the second dipole radiator 130-2 will extend at an angle of +45° with respect to the horizon when the radiating element 100 is mounted for use in a base station antenna. The sheet metal dipole arms 140-1 and 140-2 of the first dipole radiator 130-1 transmit and receive signals having a slant −45° linear polarization, while the sheet metal dipole arms 140-3 and 140-4 of second dipole radiator 130-2 transmit and receive signals having a slant +45° linear polarization.

Each sheet metal dipole arm 140 has an outer perimeter that generally defines a square, although one corner of the square is beveled. The four sheet metal dipole arms 140 are positioned next to each other so that the outer perimeter of the combination of all four sheet metal dipole arms 140-1 through 140-4 defines a radiating surface 146 that has a generally square outer perimeter. The first and second inner sides of each sheet metal dipole arm 140 are adjacent inner sides of two others of the sheet metal dipole arms 140. Adjacent dipole arms 140 are separated by a small gap so that the larger radiating surface 146 defined by the combination of all four sheet metal dipole arms 140 is more than four times larger than the smaller squares defined by the individual sheet metal dipole arms 140.

Each sheet metal dipole arm 140 is a planar element, allowing the sheet metal dipole arms 140 to be formed through a stamping operation and without any additional bending operation. Each sheet metal dipole arm 140 may comprise a conductive loop that includes a plurality of wide sections 142 and a plurality of narrowed sections 144. An average width of the wide sections 142 may be at least three times the average width of each narrowed section 144. Every two adjacent wide sections 142 are connected through a narrowed section 144. The widened sections 142 may capacitively couple with each other and the narrowed sections 144 may add inductance so that the sheet metal dipole arms 140 may have embedded LC circuits that may be tuned to pass lower frequency band currents while blocking higher frequency band currents. As a result, the sheet metal dipole arms 140 may readily transmit and receive RF signals in the low-band operating frequency range while being substantially transparent to RF energy in the mid-band and/or high-band operating frequency ranges. In other words, the low-band radiating element 100 may be cloaked with respect to mid-band and/or high-band RF radiation so that such radiation will not induce substantial currents on the low-band sheet metal dipole arms 140.

As noted above, the outer perimeter of each sheet metal dipole arm 140 has a perimeter that generally defines a square, where one corner of the square is beveled. The sheet metal dipole arms 140 are positioned so that the beveled corner of each sheet metal dipole arm 140 is positioned in the center of the radiating surface 146, forming an opening 148 therein. The distal end 118 of the feed stalk printed circuit board 110 may extend through the opening 148 so that the distal end 118 of the feed stalk printed circuit board 110 is positioned forwardly of the sheet metal dipole arms 140.

Referring to FIGS. 3A and 3E, the coupling printed circuit board 150 is mounted on the distal end 118 of the feed stalk printed circuit board 110 forwardly of the dipole arms 140. The coupling printed circuit board 150 includes a dielectric substrate 152 that has a metallization pattern 154 on a forward side thereof. A slot 156 is provided in the dielectric substrate 152. The distal end 118 of the feed stalk printed circuit board 110 includes a tab that is inserted through the slot 156 to mechanically mount the coupling printed circuit board 150 on the feed stalk printed circuit board 110. As shown in FIG. 3E, the first metallization pattern 154 comprises four large metal pads 158-1 through 158-4. Each large metal pad 158 may include a smaller metal pad 160 extending therefrom toward the slot 156. As shown in FIG. 3A, solder joints 162 are formed that electrically connect each small metal pad 160 on the coupling printed circuit board 150 to a respective one of the metal pads 124, 126 provided at the distal end 118 of the signal and ground conductors 120, 122. The solder joints 162 galvanically connect the signal conductor 120-1 and ground conductor 122-1 of the first feed line 114-1 to metal pads 158-1, 158-2, respectively, and galvanically connect the signal conductor 120-2 and ground conductor 122-2 of the second feed line 114-2 to metal pads 158-3, 158-4, respectively.

Each large metal pad 158 overlaps a respective one of the dipole arms 140 in the forward direction (i.e., an axis extending in the forward direction will pass through each metal pad 158 and an associated one of the dipole arms 140). Each metal pad 158 may overlap one of the wide sections 142 of a respective one of the dipole arms 140 so that each metal pad 158 and the wide section 142 form a capacitive connection (“capacitor”), with the dielectric substrate 152 of the coupling printed circuit board 150 serving as the dielectrics of these capacitors. Thus, each conductor of the feed lines 114 is capacitively coupled to a respective one of the dipole arms 140.

As discussed above, each ground conductor 122 on the feed stalk printed circuit board 110 includes an inductor 128, and the signal conductors 120 on the feed stalk printed circuit board 110 include narrow sections that also add inductance. Since the connection between each signal or ground conductor 120, 122 and their associated dipole arms 140 also includes the above-described capacitive connections, As such, a plurality of LC circuits are provided along the connections between each signal or ground conductor 120, 122 and their associated dipole arms 140. These LC circuits may be tuned by adjusting the actual and relative amounts of capacitance and inductance thereof to improve the impedance match between the feed lines on the feed stalk printed circuit board 110 and the dipole arms 140.

As noted above, the feed stalk of radiating clement 100 is implemented using a single, relatively small feed stalk printed circuit board 110 that includes narrow signal conductors 120. This may decrease the degree to which the feed stalk printed circuit board 110 causes the first (reflective) type of scattering discussed above. Moreover, scattering due to reflection is particularly problematic in multiband base station antennas that include multi-column beamforming arrays that are capable of scanning the generated antenna beams in the azimuth plane, as when the antenna beams are scanned the RF energy may intersect the feed stalk printed circuit boards of the low-band radiating elements at much smaller incident angles, which can result in much greater amounts of reflection. With radiating element 100, the single feed stalk printed circuit board 110 may be oriented in the transverse direction of the base station antenna in which it is mounted so that when the antenna beams of the beamforming array are scanned in the azimuth plane they intersect the thin side surface of the feed stalk printed circuit board 110, which results in far less reflection.

Referring again to FIG. 3A, the dielectric support 170 may comprise a plastic support that is mounted, for example, directly behind the dipole arms 140. Rivets or other fasteners (not shown) may be used to mount the dipole arms 140 on the dielectric support 170, although it will be appreciated that any suitable mounting mechanism may be used (including capturing the dipole arms between two dielectric support pieces). While not shown, the dielectric support 170 may include one or more rearwardly extending legs that are used, for example, to mount the dielectric support on a reflector of the base station antenna. The dielectric support 170 may ensure that the dipole arms 140 remain in fixed positions. The dielectric support 170 may include a plurality of cut-outs to reduce the weight thereof and the extent to which the dielectric support 170 impacts the RF performance of radiating element 100.

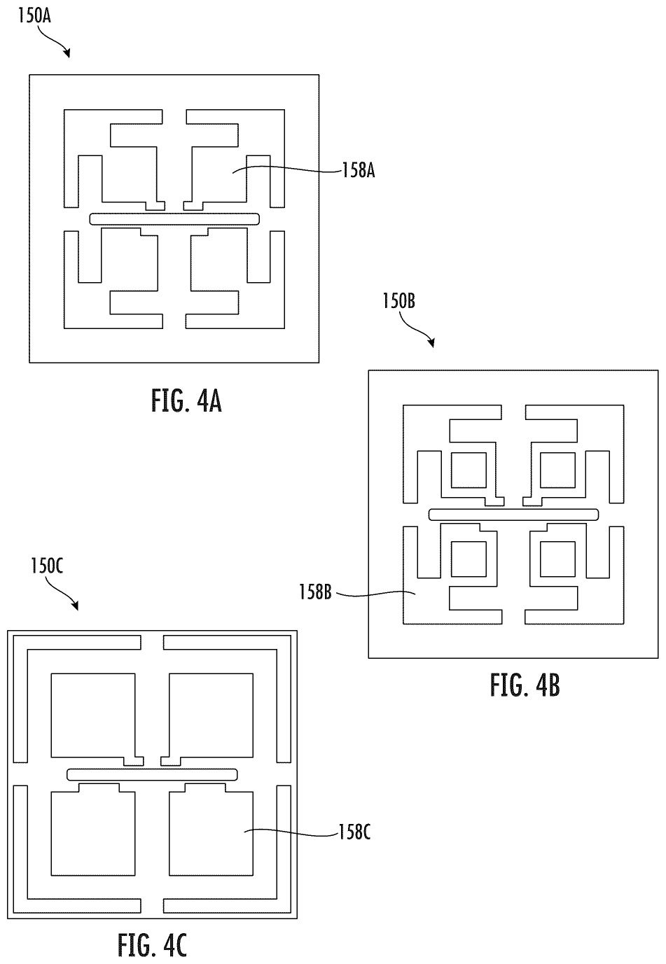

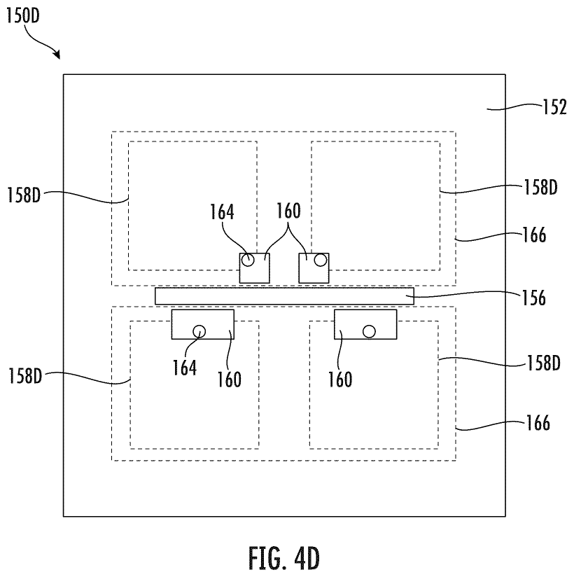

It will be appreciated that many different coupling printed circuit board designs may be used. FIGS. 4A-4C illustrate three alternative coupling printed circuit boards 150A-150C that may be used in place of coupling printed circuit board 150. Coupling printed circuit boards 150A-150C include different metal pad designs 158A-158C. It will also be appreciated that the metal pads may be formed on the rear surface of a coupling printed circuit board instead of the front surface. For example, FIG. 4D is a shadow front view of a coupling printed circuit board 150D that includes small pads 160 on a forward surface of dielectric substrate 152 that can be connected to the respective signal and ground conductors 120, 122 on the feed stalk printed circuit board 110. The small pads 160 are connected to metal pads 158D that are formed on the rear surface of dielectric substrate 152 via plated through holes 164 that extend through the dielectric substrate 152. A solder mask 166 may be formed over metal pads 158D so that the metal pads 158D capacitively couple with the respective dipole arms 240-1 through 240-4. Since the solder mask 166 may typically be much thinner than the dielectric substrate 152, increased capacitive coupling may be obtained using coupling printed circuit board 150D. This may allow using a smaller coupling printed circuit board.

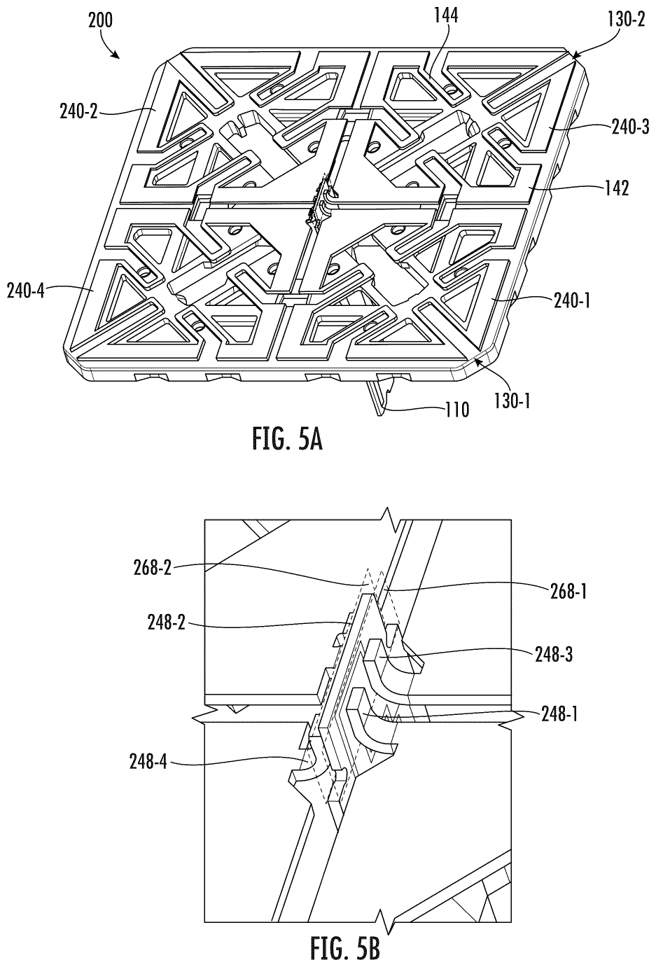

FIGS. 5A and 5B illustrate a low-band radiating clement 200 according to further embodiments of the present invention. In particular, FIG. 5A is a front perspective view of a low-band radiating clement according to further embodiments of the present invention, and FIG. 5B is an enlarged perspective front view of the electrical connections between the feed stalk printed circuit board and dipole arms of the low-band radiating clement of FIG. 5A. The radiating element 200 is similar to radiating clement 100, and hence the description below focuses on the differences between the two radiating elements 100, 200. Elements of radiating element 200 that are identical or essentially identical to corresponding elements of radiating element 100 are identified using the same reference numerals used in the description of radiating element 100 and further description of these elements will typically be omitted in the description of radiating element 200 below.

Referring first to FIG. 5A, it can be seen that radiating element 200 includes a feed stalk printed circuit board 110 which may be identical to feed stalk printed circuit board 110 of FIGS. 3B-3C, first through fourth dipole arms 240-1 through 240-4, and a dielectric support 170 which may be similar or identical to the dielectric support 170 shown in FIG. 3A. Notably, radiating element 200 does not include a coupling printed circuit board.

Referring to FIG. 5B, the primary difference between radiating elements 100 and 200 is that in radiating clement 200 the dipole arms 240-1 through 240-4 are “directly” capacitively coupled to the respective signal and ground conductors 120, 122 on the feed stalk printed circuit board 110. This approach not only eliminates any need for a coupling printed circuit board, thereby reducing the part count and cost, it also eliminates any need for solder joints along the electrical paths from the respective signal and ground conductors 120, 122 on the feed stalk printed circuit board 110 to the dipole arms 240-1 through 240-4. The elimination of these solder joints simplifies the manufacturing process and eliminates a potential source of passive intermodulation (“PIM”) distortion (as poorly formed solder joints are a well-known PIM distortion source. Radiating element 200, however, may require additional dielectric members to ensure consistent capacitive connections between the dipole arms 240 and the signal and ground conductors 120, 122 on the feed stalk printed circuit board 110.

As can best be seen in FIG. 5B, the dipole arms 240 do not include an inner beveled corner, and each dipole arm 240 further includes a forwardly-extending tab 248 (some or all of the tabs 248 could alternatively be rearwardly-extending tabs or laterally-extending tabs) that extends from the inner corner of each dipole arm 240. Each tab 248 extends generally parallel to the feed stalk printed circuit board 110 and overlaps a respective one of the signal or ground conductors 120, 122 on the feed stalk printed circuit board 110. A first solder mask 268-1 is formed on the first surface of the feed stalk printed circuit board 110 and a second solder mask 268-2 is formed on the second surface of the feed stalk printed circuit board 110. The first solder mask 268-1 is interposed in between the first tab 248-1 and the first signal conductor 120-1, and in between the third tab 248-3 and the second signal conductor 120-2. The second solder mask 268-2 is interposed in between the second tab 248-2 and the first ground conductor 122-1, and in between the fourth tab 248-4 and the second ground conductor 122-2. The first and second solder masks 268-1, 268-2 thus act as the dielectric between the four capacitive connections between the signal and ground conductors 120, 122 and the respective four dipole arms 240-1 through 240-4.

Referring to both FIGS. 3A-3E and 5A-5B, it can be seen that pursuant to some embodiments of the present invention, radiating elements 100, 200 are provided comprise a dielectric support 170, first through fourth sheet metal dipole arms 140-1-140-4 or 240-1, 240-2 on the dielectric support 170, and a feed stalk printed circuit board 110. The feed stalk printed circuit board 110 includes a first RF transmission line that has a first signal conductor 120-1 that is coupled to the first sheet metal dipole arm 140-1; 240-2 through at least a first capacitive connection and a first ground conductor 122-1 that is coupled to the second sheet metal dipole arm 140-2; 240-2 through at least a second capacitive connection, and a second RF transmission line that has a second signal conductor 120-2 that is coupled to the third sheet metal dipole arm 140-3; 240-3 through at least a third capacitive connection and a second ground conductor 122-2 that is coupled to the fourth sheet metal dipole arm 140-4; 240-4 through at least a fourth capacitive connection.

In some embodiments, the radiating element 100 comprises a coupling printed circuit board 150 that is mounted on the feed stalk printed circuit board 110. This coupling printed circuit board 150 may include a first metal pad 158-1 that is electrically connected to the first signal conductor 120-1 through a first galvanic connection, a second metal pad 158-2 that is electrically connected to the first ground conductor 122-1 through a second galvanic connection, a third metal pad 158-3 that is electrically connected to the second signal conductor 120-2 through a third galvanic connection, and a fourth metal pad 158-4 that is electrically connected to the second ground conductor 122-2 through a fourth galvanic connection. In such embodiments, the first metal pad 158-1 may be capacitively coupled to the first sheet metal dipole arm 140-1, the second metal pad 158-1 may be capacitively coupled to the second sheet metal dipole arm 140-2, the third metal pad 158-3 may be capacitively coupled to the third sheet metal dipole arm 140-3, and the fourth metal pad 158-4 may be capacitively coupled to the fourth sheet metal dipole arm 140-4. The base 116 of the feed stalk printed circuit board 110 may be positioned rearwardly of the sheet metal dipole arms 140 and the coupling printed circuit board 150 may be positioned forwardly of the sheet metal dipole arms 140. For example, the sheet metal dipole arms 140 may be positioned in between the dielectric support 170 and the coupling printed circuit board 150. In some embodiments, the metal pads 158 may be on a forward surface of a dielectric substrate 152 of the coupling printed circuit board 150.

A distal end 118 of the feed stalk printed circuit board 110 that is opposite the base 116 may extend through a slot 156 in the coupling printed circuit board 150. Each of the first through fourth sheet metal dipole arms 140 may be positioned adjacent two other of the first through fourth sheet metal dipole arms 140 so that together the first through fourth sheet metal dipole arms 140 form a radiating surface 146 that has a square perimeter. The feed stalk printed circuit board 110 may extend through an opening 148 in the center of the radiating surface 146.

In these embodiments, the first ground conductor 122-1 may include a first meandered trace segment 128 and the second ground conductor 122-2 may include a second meandered trace segment 128. The first meandered trace segment 128 and the second capacitive connection together form a first LC circuit that increases an impedance of the first RF transmission line on the feed stalk printed circuit board 110, and the second meandered trace segment 110 and the fourth capacitive connection together form a second LC circuit that increases an impedance of the second RF transmission line on the feed stalk printed circuit board 110. The first signal conductor 120-1 may be coupled to the first sheet metal dipole arm 140-1 through both a solder joint and the first capacitive connection

In other embodiments, the coupling printed circuit board 150 may be omitted. For example, in radiating element 200 the first sheet metal dipole arm 240-1 may include a first tab 248-1 that extends parallel to the feed stalk printed circuit board 110 and is configured to capacitively couple with the first signal conductor 120-1 to form the first capacitive connection, the second sheet metal dipole arm 240-2 may include a second tab 248-2 that extends parallel to the feed stalk printed circuit board 110 and is configured to capacitively couple with the first ground conductor 122-1 to form the second capacitive connection, the third sheet metal dipole arm 240-3 may include a third tab 248-3 that extends parallel to the feed stalk printed circuit board 110 and is configured to capacitively couple with the second signal conductor 120-2 to form the third capacitive connection, and the fourth sheet metal dipole arm 240-4 may include a fourth tab 248-4 that extends parallel to the feed stalk printed circuit board 110 and is configured to capacitively couple with the second ground conductor 122-2 to form the fourth capacitive connection. In such embodiments, the radiating clement 200 may further comprise a first solder mask 268-1 on a first side of the feed stalk printed circuit board 110 that is positioned between the first tab 248-1 and the first signal conductor 120-1 and a second solder mask 268-2 on a second side of the feed stalk printed circuit board 110 that is positioned between the second tab 248-2 and the first ground conductor 122-1.

Referring to FIGS. 3A-3E, pursuant to further embodiments of the present invention, radiating elements 100 are provided that comprise a plurality of sheet metal dipole arms 140, a feed stalk printed circuit board 110, and a coupling printed circuit board 150 that is mounted on the feed stalk printed circuit board 110 and configured to capacitively couple RF signals between the feed stalk printed circuit board 110 and the sheet metal dipole arms 140.

Referring to FIGS. 5A-5B, pursuant to further embodiments of the present invention, radiating elements 200 are provided that comprise a dielectric support 170, first and second sheet metal dipole arms 240-1, 240-2 on the dielectric support 170, and a feed stalk printed circuit board 110 that includes a first RF transmission line that has a first signal conductor 120-1 and a first ground conductor 122-1. The first sheet metal dipole arm 240-1 includes a first tab 248-1 that is configured to capacitively couple with the first signal conductor 120-1 and the second sheet metal dipole arm 240-2 includes a second tab 248-2 is configured to capacitively couple with the first ground conductor 122-2. The first and second tabs 248-1, 248-2 may extend parallel to the feed stalk printed circuit board 110. A first solder mask 268-1 may be formed on a first side of the feed stalk printed circuit board 110 and positioned between the first tab 248-1 and the first signal conductor 120-1, and a second solder mask 268-2 may be formed on a second side of the feed stalk printed circuit board 110 and positioned between the second tab 248-2 and the first ground conductor 122-1.

It will be appreciated that many modifications may be made to the above-described low-cost radiating elements without departing from the scope of the present invention. As one example, the feed stalk printed circuit boards may include cloaked RF transmission lines as disclosed, for example, in PCT Patent Application Serial Nos. PCT/CN23/070056 and PCT/US24/10094, the entire content of each of which is hereby incorporated herein by reference. As another example, the coupling printed circuit board 150 may be mounted rearwardly of the dipole arms 140 in other embodiments. The dipole arms 140, 240 may include any suitable cloaking design. Any suitable dielectric substrate 170 may be used, and the dielectric substrate may be omitted in some embodiments, particularly if the dipole arms 140, 240 are sufficiently rigid. Different feed stalk printed circuit boards may be used, and in some cases two feed stalk printed circuit boards may be used. Finally, while radiating elements 100, 200 are low-band radiating elements, it will be appreciated that they can be scaled in size and turned into mid-band or high-band radiating elements in other embodiments.

Embodiments of the present invention have been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Herein, the term “substantially” means within +/−10%.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Aspects and elements of all of the embodiments disclosed above can be combined in any way and/or combination with aspects or elements of other embodiments to provide a plurality of additional embodiments.

1. A radiating element, comprising:
a dielectric support;
first through fourth sheet metal dipole arms on the dielectric support; and
a feed stalk printed circuit board that includes:
a first radio frequency (“RF”) transmission line that has a first signal conductor that is coupled to the first sheet metal dipole arm through at least a first capacitive connection and a first ground conductor that is coupled to the second sheet metal dipole arm through at least a second capacitive connection; and
a second RF transmission line that has a second signal conductor that is coupled to the third sheet metal dipole arm through at least a third capacitive connection and a second ground conductor that is coupled to the fourth sheet metal dipole arm through at least a fourth capacitive connection.

2. The radiating element of claim 1, further comprising a coupling printed circuit board that is mounted on the feed stalk printed circuit board, the coupling printed circuit board including a first metal pad that is electrically connected to the first signal conductor through a first galvanic connection, a second metal pad that is electrically connected to the first ground conductor through a second galvanic connection, a third metal pad that is electrically connected to the second signal conductor through a third galvanic connection, and a fourth metal pad that is electrically connected to the second ground conductor through a fourth galvanic connection.

3. The radiating element of claim 2, wherein the first metal pad is capacitively coupled to the first sheet metal dipole arm, the second metal pad is capacitively coupled to the second sheet metal dipole arm, the third metal pad is capacitively coupled to the third sheet metal dipole arm, and the fourth metal pad is capacitively coupled to the fourth sheet metal dipole arm.

4-6. (canceled)

7. The radiating element of claim 1, wherein the first ground conductor includes a first meandered trace segment and the second ground conductor includes a second meandered trace segment.

8-9. (canceled)

10. The radiating element of claim 1, wherein each of the first through fourth sheet metal dipole arms is positioned adjacent two other of the first through fourth sheet metal dipole arms so that together the first through fourth sheet metal dipole arms form a radiating surface that has a square perimeter.

11. (canceled)

12. The radiating element of claim 1, wherein the first signal conductor is coupled to the first sheet metal dipole arm through both a solder joint and the first capacitive connection.

13. The radiating element of claim 1, wherein the first sheet metal dipole arm includes a first tab that extends parallel to the feed stalk printed circuit board and is configured to capacitively couple with the first signal conductor to form the first capacitive connection, the second sheet metal dipole arm includes a second tab that extends parallel to the feed stalk printed circuit board and is configured to capacitively couple with the first ground conductor to form the second capacitive connection, the third sheet metal dipole arm includes a third tab that extends parallel to the feed stalk printed circuit board and is configured to capacitively couple with the second signal conductor to form the third capacitive connection, and the fourth sheet metal dipole arm includes a fourth tab that extends parallel to the feed stalk printed circuit board and is configured to capacitively couple with the second ground conductor to form the fourth capacitive connection.

14-15. (canceled)

16. A radiating element, comprising:
a plurality of sheet metal dipole arms;
a feed stalk printed circuit board; and
a coupling printed circuit board that is mounted on the feed stalk printed circuit board and configured to capacitively couple radio frequency (“RF”) signals between the feed stalk printed circuit board and the sheet metal dipole arms.

17. The radiating element of claim 16, wherein a base of the feed stalk printed circuit board is positioned rearwardly of the dipole arms and the coupling printed circuit board is positioned forwardly of the dipole arms.

18. The radiating element of claim 16, wherein the first and second conductors of a first RF transmission line of the feed stalk printed circuit board are galvanically connected to respective first and second metal pads on the coupling printed circuit board.

19. The radiating element of claim 18, wherein the first and second metal pads are on a forward surface of a dielectric substrate of the coupling printed circuit board.

20-21. (canceled)

22. The radiating element of claim 16, wherein the feed stalk printed circuit board comprises a first RF transmission line that is coupled to first and second of the sheet metal dipole arms and a second RF transmission line that is coupled to third and fourth of the sheet metal dipole arms.

23. The radiating element of claim 22, wherein the coupling printed circuit board includes a first metal pad that is galvanically connected to a signal conductor of the first RF transmission line, a second metal pad that is galvanically connected to a ground conductor of the first RF transmission line, a third metal pad that is galvanically connected to a signal conductor of the second RF transmission line, and a fourth metal pad that is galvanically connected to a ground conductor of the second RF transmission line.

24. The radiating element of claim 23, wherein the plurality of sheet metal dipole arms comprises first through fourth sheet metal dipole arms, and the first through fourth metal pads are capacitively coupled to respective ones of first through fourth sheet metal dipole arms.

25. The radiating element of claim 16, wherein the feed stalk printed circuit board includes at least one tab that extends through a slot in the coupling printed circuit board.

26. A radiating element, comprising:
a dielectric support;
a first sheet metal dipole arm on the dielectric support;
a second sheet metal dipole arm on the dielectric support; and
a feed stalk printed circuit board that includes a first radio frequency (“RF”) transmission line that includes a first signal conductor and a first ground conductor;
wherein the first sheet metal dipole arm includes a first tab that is configured to capacitively couple with the first signal conductor and the second sheet metal dipole arm includes a second tab is configured to capacitively couple with the first ground conductor.

27. The radiating element of claim 26, wherein the first and second tabs extend parallel to the feed stalk printed circuit board.

28. The radiating element of claim 26, further comprising a first solder mask on a first side of the feed stalk printed circuit board that is positioned between the first tab and the first signal conductor and a second solder mask on a second side of the feed stalk printed circuit board that is positioned between the second tab and the first ground conductor.

29-31. (canceled)

32. The radiating element of claim 26, wherein the first RF transmission line includes a meandered trace segment.

33. The radiating element of claim 32, wherein the meandered trace segment and a capacitive connection between the first pad and the first signal conductor together form a capacitor-inductor circuit that increases an impedance of the first RF transmission line.
